(19) United States
(12) Patent Application Publication
(10) Pub. No.: US 2012/0061800 A1
(43) Pub. Date: Mar. 15, 2012

(54) CAPACITOR ELEMENT, MANUFACTURING METHOD THEREOF AND SEMICONDUCTOR DEVICE

(75) Inventor: Toshiyuki HIROTA, Tokyo (JP)

(73) Assignee: ELPIDA MEMORY, INC., Tokyo (JP)

(21) Appl. No.: 13/046,437

(22) Filed: Mar. 11, 2011

(30) Foreign Application Priority Data
Mar. 15, 2010 (JP) 2010-057813

(51) Int. Cl. H01L 29/02

(52) U.S. Cl. 257/532; 257/E29.002

(57) ABSTRACT

A semiconductor device includes a first capacitive insulating film, a first electrode, and a first barrier film. The first electrode has a first surface containing nitrogen. The first barrier film is between the first capacitive insulating film and the first electrode. The first barrier film faces the first surface of the first electrode. The first barrier film includes zinc oxide. The first barrier film is conductive.

### BACKGROUND OF THE INVENTION

1. Field of the Invention

The present invention relates to a capacitor element, a manufacturing method thereof, and a semiconductor device.

Priority is claimed on Japanese Patent Application No. 2010-057813, Mar. 15, 2010, the content of which is incorporated herein by reference.

2. Description of the Related Art

Recently, as miniaturization of semiconductor devices such as a DRAM device has been required, devices with a metal-insulator-metal (MIM) structure have been employed as a capacitor element having a large capacitance.

Japanese Unexamined Patent Application, First Publication, No. JP-A-2007-081265 and Japanese Unexamined Patent Application, Second Publication, No. JP-A-2002-314072 disclose that a capacitor element having an MIM structure is formed using a metal nitride such as titanium nitride (TiN) for forming an electrode and zirconium oxide (ZrO₂) as a material of a high insulating film.

High capacitance, a small leakage current, and the like are necessary for a capacitor element used in a memory cell such as a DRAM device.

In general, the capacitor element is known for the following property. Capacitance increases as the thickness of a capacitive insulating film between two electrodes of the capacitor element is thinned. However, the leakage current also increases as the thickness of the capacitive insulating film is thinned. There has been disclosed, in the above applications, technology for reducing the leakage current by stacking the capacitive insulating film and a barrier film between the two electrodes.

As such technology, Japanese Unexamined Patent Application, First Publication, No. JP-A-2007-081265 discloses a capacitor element having a structure in which hafnium oxide containing at least one of aluminum (Al) and silicon (Si) or a barrier film including zirconium oxide is provided between a capacitive insulating film including hafnium oxide or zirconium oxide and an electrode. Furthermore, Japanese Unexamined Patent Application, Second Publication, No. JP-A-2002-314072 discloses a capacitor element having a structure in which a capacitive insulating film including zirconium oxide and a barrier film including aluminum oxide are stacked. Furthermore, Japanese Unexamined Patent Application, Third Publication, No. JP-A-2000-208720 discloses a capacitor element having a structure in which a barrier film including at least one of a metal carbide, a metal nitride, a metal boride, a metal carbonitride, and silicon carbide is stacked on a capacitive insulating film including zirconium oxide.

### SUMMARY

In one embodiment, a semiconductor device may include, but is not limited to, a first capacitive insulating film, a first electrode, and a first barrier film. The first electrode has a first surface containing nitrogen. The first barrier film is between the first capacitive insulating film and the first electrode. The first barrier film faces the first surface of the first electrode. The first barrier film includes zinc oxide. The first barrier film is conductive.

In another embodiment, a semiconductor device may include, but is not limited to, a first electrode, a second electrode, a capacitive insulating film, and a first barrier film. The first electrode contains a first metal nitride. The second electrode contains a second metal nitride. The capacitive insulating film is between the first and second electrodes. The capacitive insulating film includes one of zirconium oxide and hafnium oxide. The first barrier film is between the second electrode and the capacitive insulating film. The first barrier film is in contact with the second electrode and the capacitive insulating film. The first barrier film includes zinc oxide. The first barrier film contains at least one of boron, aluminum, and gallium.

In still another embodiment, a semiconductor device may include, but is not limited to, a transistor and a capacitor element electrically coupled to the transistor. The capacitor element may include, but is not limited to, a first electrode, a second electrode, a first capacitive insulating film, and a first barrier film. The first electrode is electrically coupled to the transistor. The first electrode contains a first metal nitride. The second electrode contains a second metal nitride. The capacitive insulating film is between the first and second electrodes. The capacitive insulating film includes one of zirconium oxide and hafnium oxide. The first barrier film is between the second electrode and the capacitive insulating film. The first barrier film is in contact with the second electrode and the capacitive insulating film. The first barrier film includes zinc oxide. The first barrier film contains at least one of boron, aluminum, and gallium.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a capacitor element in a step involved in a method of forming a semiconductor device in accordance with one embodiment of the present invention;

FIG. 2 is a fragmentary cross sectional elevation view illustrating a capacitor element in a step, subsequent to the step of FIG. 1, involved in a method of forming a semiconductor device in accordance with one embodiment of the present invention;

FIG. 3 is a fragmentary cross sectional elevation view illustrating a capacitor element in a step, subsequent to the step of FIG. 2, involved in a method of forming a semiconductor device in accordance with one embodiment of the present invention;

FIG. 4 is a fragmentary cross sectional elevation view illustrating a capacitor element in accordance with one embodiment of the present invention;

FIG. 5 is a flow chart showing a part of steps involved in a method of forming a semiconductor device in accordance with one embodiment of the present invention;

FIG. 6 is a fragmentary cross sectional elevation view illustrating a capacitor element in accordance with another embodiment of the present invention;

FIG. 7 is a fragmentary cross sectional elevation view illustrating a capacitor element in accordance with another embodiment of the present invention;

FIG. 8 is a fragmentary plan view illustrating a semiconductor device in accordance with another embodiment of the present invention;

FIG. 9 is a fragmentary cross sectional elevation view, taken along an A-A′ line of FIG. 8, illustrating the semiconductor device in accordance with another embodiment of the present invention;

FIG. 10 is a fragmentary cross sectional elevation view illustrating a capacitor element in a step involved in a method of forming the semiconductor device of FIG. 9 in accordance with another embodiment of the present invention;

FIG. 11 is a fragmentary cross sectional elevation view illustrating a capacitor element in a step involved in a method of forming the semiconductor device of FIG. 9 in accordance with another embodiment of the present invention; and

FIG. 12 is a fragmentary cross sectional elevation view illustrating a capacitor element in accordance with another embodiment of the present invention.

### DETAILED DESCRIPTION OF THE PREFERRED EMBODIMENTS

Before describing the present invention, the related art will be explained in detail, in order to facilitate the understanding of the present invention.

As disclosed in Japanese Unexamined Patent Application, First Publication, No. JP-A-2007-081265 and Japanese Unexamined Patent Application, Second Publication, No. JP-A-2002-314072, when the barrier film is formed of an insulator, the total capacitance of the capacitor element may be reduced by parasitic capacitance of the insulator.

Furthermore, if an electrode including a metal nitride is formed to make direct contact with a capacitive insulating film including zirconium oxide, nitrogen can be easily diffused into zirconium oxide from a metal nitride typically when the surface of the capacitive insulating film is directly exposed to a nitrogen-containing atmosphere for forming metal nitride. In zirconium oxide in the capacitive insulating film, nitrogen serves as negative ions similarly to oxygen. Due to this, oxygen in zirconium oxide can be removed from zirconium oxide. Therefore, removal of oxygen from zirconium oxide will cause an energy level in the band gap of zirconium oxide. Removal of oxygen from zirconium oxide will result in poor crystallinity. Consequently, the leakage current may be increased, or the dielectric constant may be reduced.

The leakage current may be increased in the known method of forming the electrode including metal nitride in direct contact with zirconium oxide. On the other hand, if the barrier film including an insulator is used in order to suppress the leakage current, the capacitance is reduced. Therefore, it is difficult to achieve both of reduction of the leakage current and increase of the capacitance in the known capacitor element.

As described above, the known capacitor element has a structure in which the capacitive insulating film (the zirconium oxide film) is interposed between two electrodes including metal nitride such as titanium nitride. Also, the insulating barrier film is interposed between one of the electrodes and the capacitive insulating film. In the structure, the lower limit to equivalent oxide thickness (EOT) is estimated at about 0.9 nm when considering the upper limit to the leakage current required for the memory cell. The EOT can be calculated to be the necessary thickness for obtaining the same static capacitance per unit area when the capacitive insulating film is a silicon oxide film with a dielectric constant of 3.9.

As described above, it is difficult to form, without increase in the leakage current, the capacitor element including the zirconium oxide capacitive insulating film having the EOT value which is smaller than 0.9 nm.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a first capacitive insulating film, a first electrode, and a first barrier film. The first electrode has a first surface containing nitrogen. The first barrier film is between the first capacitive insulating film and the first electrode. The first barrier film faces the first surface of the first electrode. The first barrier film includes zinc oxide. The first barrier film is conductive.

In some cases, the semiconductor device may include, but is not limited to, the first barrier film with a thickness of 0.5 nm to 8 nm.

In some cases, the semiconductor device may include, but is not limited to, the first barrier film containing an impurity. The first barrier film has a concentration of the impurity in the range of 1×10²⁰ atoms/cm³ to 1×10²² atoms/cm³.

In some cases, the semiconductor device may include, but is not limited to, the first barrier film containing at least one of boron, aluminum, and gallium.

In some cases, the semiconductor device may include, but is not limited to, the first barrier film including at least a first atomic layer of zinc oxide and a second atomic layer of one of boron oxide, aluminum oxide, and gallium oxide.

In some cases, the semiconductor device may include, but is not limited to, the first barrier film including alternate lamination of first atomic layers of zinc oxide and second atomic layers of one of boron oxide, aluminum oxide, and gallium oxide.

In some cases, the semiconductor device may include, but is not limited to, the first surface of the first electrode including metal nitride.

In some cases, the semiconductor device may include, but is not limited to, the first capacitive insulating film including one of zirconium oxide and hafnium oxide.

In some cases, the first capacitive insulating film may include, but is not limited to, first and second capacitive layers and an aluminum oxide layer between the first and second capacitive layers.

In some cases, the semiconductor device may further include, but is not limited to, a second electrode in contact with the first capacitive insulating film. The first capacitive insulating film and the first barrier film are between the first and second electrodes.

In some cases, the semiconductor device may further include, but is not limited to, a second barrier film and a second electrode. The second barrier film is in contact with the first capacitive insulating film. The second barrier film includes zinc oxide. The second barrier film contains at least one of boron, aluminum, and gallium. The second electrode is in contact with the second barrier film.

In another embodiment, a semiconductor device may include, but is not limited to, a first electrode, a second electrode, a capacitive insulating film, and a first barrier film. The first electrode contains a first metal nitride. The second electrode contains a second metal nitride. The capacitive insulating film is between the first and second electrodes. The capacitive insulating film includes one of zirconium oxide and hafnium oxide. The first barrier film is between the second electrode and the capacitive insulating film. The first barrier film is in contact with the second electrode and the capacitive insulating film. The first barrier film includes zinc oxide. The first barrier film contains at least one of boron, aluminum, and gallium.

In some cases, the semiconductor device may include, but is not limited to, the first barrier film including at least a first atomic layer of zinc oxide and a second atomic layer of one of boron oxide, aluminum oxide, and gallium oxide.

In some cases, the semiconductor device may include, but is not limited to, the first barrier film including alternate lamination of first atomic layers of zinc oxide and second atomic layers of one of boron oxide, aluminum oxide, and gallium oxide.

In some cases, the semiconductor device may include, but is not limited to, the first barrier film with a thickness of 0.5 nm to 8 nm.

In some cases, the semiconductor device may further include, but is not limited to, a second barrier film between the first electrode and the first capacitive insulating film. The second barrier film includes zinc oxide. The second barrier film contains at least one of boron, aluminum, and gallium.

In still another embodiment, a semiconductor device may include, but is not limited to, a transistor and a capacitor element electrically coupled to the transistor. The capacitor element may include, but is not limited to, a first electrode, a second electrode, a capacitive insulating film, and a first barrier film. The first electrode contains a first metal nitride. The first electrode is electrically coupled to the transistor. The second electrode contains a second metal nitride. The capacitive insulating film is between the first and second electrodes. The capacitive insulating film includes one of zirconium oxide and hafnium oxide. The first barrier film is between the second electrode and the capacitive insulating film. The first barrier film is in contact with the second electrode and the capacitive insulating film. The first barrier film includes zinc oxide. The first barrier film contains at least one of boron, aluminum, and gallium.

In some cases, the semiconductor device may include, but is not limited to, the first barrier film including at least a first atomic layer of zinc oxide and a second atomic layer of one of boron oxide, aluminum oxide, and gallium oxide.

In some cases, the semiconductor device may include, but is not limited to, the first barrier film including alternate lamination of first atomic layers of zinc oxide and second atomic layers of one of boron oxide, aluminum oxide, and gallium oxide.

In some cases, the semiconductor device may include, but is not limited to, the first barrier film with a thickness of 0.5 nm to 8 nm.

Hereinafter, a semiconductor device and a method of manufacturing the semiconductor device according to an embodiment of the invention will be described in detail with reference to the drawings. In the embodiment, a dynamic random access memory (DRAM) will be described. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples and may be different from those of an actual structure, electrode structure, and semiconductor device. The invention is not limited thereto and may be appropriately modified within a scope which does not deviate from the concept of the invention.

### First Embodiment

Hereinafter, the configuration of a capacitor element according to a first embodiment of the present invention will be described with reference to FIG. 4.

The capacitor element according to the present embodiment may include, but is not limited to, a first electrode (a lower electrode) 3, a first capacitive insulating film 4, a first barrier film 5, and a second electrode (an upper electrode) 6, which are formed over a semiconductor substrate 1 and an interlayer insulating film 2.

The semiconductor substrate 1 may be a silicon substrate. The interlayer insulating film 2, for example, the silicon oxide (SiO₂) interlayer insulating film 2 is formed thereon. The first electrode 3 including a first metal nitride such as titanium nitride (TiN) is formed on the interlayer insulating film 2. As the first electrode 3, a stacked structure film (TiN/Ti film) obtained by depositing titanium nitride on titanium (Ti) may be used, as well as a metal nitride film including a single layer.

The first capacitive insulating film 4 includes zirconium oxide or hafnium oxide (HfO₂). The first capacitive insulating film 4 is formed to cover the first electrode 3.

The first barrier film 5 includes a zinc oxide film doped with at least one of boron (B), aluminum (Al) and gallium (Ga) as impurity. The first barrier film 5 is formed to cover the first capacitive insulating film 4. In some cases, the first barrier film 5 may be formed with a thickness of 0.5 nm to 8 nm. In other cases, the first barrier film 5 may be formed with a thickness of 1 nm to 8 nm. In other cases, the first barrier film 5 may be formed with a thickness of 2 nm to 8 nm. The first barrier film 5 with a thickness in these ranges makes it possible to suppress diffusion of nitrogen from the second electrode 6 into the first capacitive insulating film 4. On the other hand, if the thickness of the first barrier film 5 is smaller than 0.5 nm, it is not preferable because it is not easy to sufficiently suppress the diffusion of the nitrogen into the first capacitive insulating film 4. Furthermore, if the thickness of the first barrier film 5 exceeds 8 nm, it is not preferable because process-ability as a capacitor element is reduced and an electrical resistance value is increased.

The thickness of the first barrier film 5 may be 5 nm or less when the capacitor element is applied to the generation of 50 nm or less of the DRAMs. In this case, the thickness of the first barrier film 5 may be 4 nm or less. The capacitor element has a three-dimensional structure with a short distance between electrodes. The first barrier film 5 with a thickness in these ranges is high in gap-filling property.

The first barrier film 5 in the present embodiment includes a stack of zinc oxide atomic layers and oxide atomic layers of the impurity. Thus, the stack forms, as a whole, as an n-type zinc oxide film.

The first barrier film 5 may have a concentration of the impurity in the range of 1×10²⁰ atoms/cm³ to 1×10²² atoms/cm³. For example, the first barrier film 5 may have a concentration of the impurity at approximately 1×10²¹ atoms/cm³. The first barrier film 5 with the concentration of the impurity in this range may have sufficiently high conductivity.

The second electrode 6, for example, includes a second metal nitride such as titanium nitride (TiN). As the second metal nitride, metal nitride may be used alone or in combination with other materials. In some cases, a stacked film may be used, which has been obtained by depositing at least one of a tungsten (W) film, an impurity-containing polycrystalline silicon film on a titanium nitride film. In other cases, a single layer of metal nitride may be used. The present embodiment can be effective in a typical case, but not limited thereto, where the second electrode 6 has a metal nitride portion which is in contact with the first barrier film 5.

As described above, the capacitor element having the MIM structure according to the present embodiment is formed.

Hereinafter, the manufacturing method of the capacitor element according to the first embodiment of the present invention will be described with the accompanying drawings.

The manufacturing method of the capacitor element according to the present embodiment may typically include, but is not limited to, the following steps. The manufacturing method may include forming the first electrode 3, forming the first capacitive insulating film 4 on the first electrode 3, forming the first barrier film 5 on the first capacitive insulating film 4, and forming the second electrode 6 on the first barrier film 5.

### Step of Forming the First Electrode 3

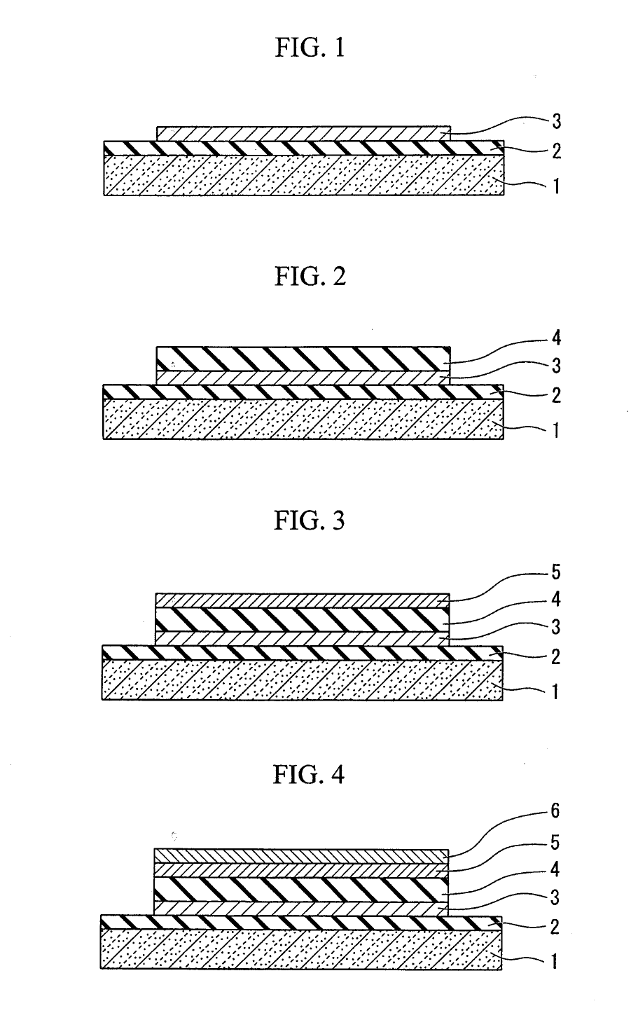

The first electrode 3 is formed as illustrated in FIG. 1. The interlayer insulating film 2 including silicon oxide or the like is formed on the semiconductor substrate 1. The first electrode 3 including the first metal nitride is formed on the interlayer insulating film 2. As the first metal nitride, it is preferable to use titanium nitride (TiN). Since the titanium nitride has better heat resistance property and process-ability than other metal nitrides, it is suitable as an electrode of the capacitor element.

At this time, when forming the first electrode 3 using the titanium nitride, it may use, for example, a chemical vapor deposition (CVD) method or an atomic layer deposition (ALD) method using TiCl₄ and NH₃ as source gases. First, a titanium nitride film is deposited on the interlayer insulating film 2. The titanium nitride film is then patterned in a predetermined shape by dry etching process using a photoresist film as a mask. In this way, the first electrode 3 is formed. As the first electrode 3, a stacked structure film (TiN/Ti film) or the like obtained by depositing titanium nitride on titanium (Ti) may be used, and instead a metal nitride may be used as a single substance.

### Step of Forming the First Capacitive Insulating Film 4

The first capacitive insulating film 4 including a zirconium oxide film is formed on the first electrode 3 as illustrated in FIG. 2. When forming the first capacitive insulating film 4, an ALD method using a Zr precursor as a source gas may be used. A typical example of the Zr precursor may be, but is not limited to, metallo-organic complexes such as tetrakis (ethylmethylamino) zirconium (Zr[N(CH₃)CH₂CH₃]₄: TEMAZ). For example, other Zr precursors may be used.

As an oxidizing agent, oxygen (O₂), ozone (O₃), steam (H₂) or a mixed gas thereof may be used, or an oxidizing agent such as a mixed gas of these gases and nitrogen gas may be used. The material of the first capacitive insulating film 4 is not limited to zirconium oxide. For example, the first capacitive insulating film 4 may be formed using hafnium oxide (HfO₂).

The thickness of the first capacitive insulating film 4 should not be limited to a particular thickness, but may be decided according to a permissive leakage current and a capacitance value of the capacitor. Depending on the necessary conditions for suppressing leakage current and ensuring the lower limit value of capacitance, the thickness of the first capacitive insulating film 4 may be formed with a thickness of about 7 nm or 8 nm

### Step of Forming the First Barrier Film 5

The first barrier film 5 is formed on the first capacitive insulating film 4 as illustrated in FIG. 3. As a material of the first barrier film 5, a zinc oxide film doped with at least one of boron, aluminum and gallium as an impurity is used. Zinc oxide is a kind of oxide semiconductor and may function as an n-type semiconductor by adding the group 3B element. As the group 3B element used in the present embodiment, it may use at least one of boron (B), gallium (Ga) and aluminum (Al).

The first barrier film 5 including the material as described above is formed between the first capacitive insulating film 4 and the second electrode 6, which will be described later. According to this structure, it is possible to prevent the capacitance of the capacitor element from being reduced. Also, it is possible to suppress the diffusion of nitrogen from the second electrode 6 to the first capacitive insulating film 4.

As a method for forming the first barrier film 5, for example, an ALD method using a Zn precursor as a source gas may be used. As the Zn precursor, diethylzinc (DEZn) may be used, but is not limited thereto. For example, other Zn precursors may be used. Furthermore, as an oxidizing agent, oxygen (O₂), ozone (O₃), steam (H₂O) or a mixed gas thereof may be used, or an oxidizing agent such as a mixed gas of these gases and nitrogen gas may be used.

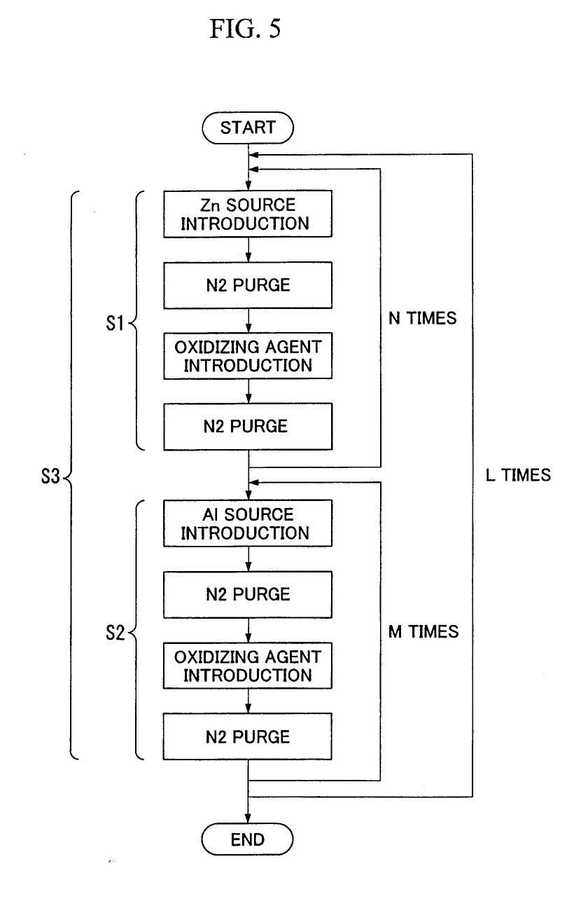

FIG. 5 is a flowchart showing processes for forming the first barrier film 5 containing, for example, aluminum as an impurity, using an ALD method. A manufacturing method of the first barrier film 5 may include, but is not limited to, the following steps. The step S1 includes forming a zinc oxide film using an ALD method by introducing a source gas (Zn source gas) onto a base including the semiconductor substrate 1 and the interlayer insulating film 2. The step S2 includes forming an oxide film including an impurity element. Hereinafter, each step will be sequentially described.

Before taking the above steps, a film forming apparatus (not illustrated) is prepared. The film forming apparatus includes a reaction chamber for deposition of a metal film using an ALD method, and a gas introduction system capable of introducing an oxidizing agent and a source gas. The deposition temperature in the reaction chamber of the film forming apparatus may be set according to condition for forming the zinc oxide film.

A substrate is prepared which has the first electrode 3 and the first capacitive insulating film 4 for the capacitor element. Next, the substrate is installed in the reaction chamber of the film forming apparatus.

### Step S1

The substrate is installed in the reaction chamber of the ALD apparatus. Next, a Zn source gas (Zn precursor) is introduced into the reaction chamber and a zinc film is deposited on the surface of the first capacitive insulating film 4. Then, the Zn source gas is discharged while N₂ gas for purging is introduced into the reaction chamber. Then, oxygen (O₂), ozone (O₃), steam (H₂O) or a mixed gas thereof, or an oxidizing agent such as a mixed gas of these gases and nitrogen gas is introduced into the reaction chamber. Purging is then performed using the N₂ gas. According to these processes, a zinc oxide atomic layer is formed. Step S1 is repeated N times (N is the positive integer), so that a zinc oxide thin film is formed.

### Step S2

Then, in step S2, an oxide film including an impurity element (an aluminum oxide film in this embodiment) is formed.

First, an Al source gas (Al precursor) is introduced into the reaction chamber and is adsorbed into the surface of the zinc oxide thin film. At this time, as the Al source gas, trimethylaluminum (TMA) can be used.

The N₂ gas for purging is introduced into the reaction chamber and the Al source gas is discharged. Then, oxygen (O₂), ozone (O₃), steam (H₂O) or a mixed gas thereof, or an oxidizing agent such as a mixed gas of these gases and nitrogen gas is introduced into the reaction chamber. Purging is performed using the N₂ gas, so that an aluminum oxide atomic layer is deposited. Step S2 is repeated M times (M is the positive integer), so that an aluminum oxide thin film is formed.

At this time, it not necessary to repeat the set of the steps S1 and S2. For example, after alternate-repeating step S1 and step S2 is performed, and the repeating processes may be terminated with the step S1.

The cycle (step S3) including the above-described step S1 and step S2 may be repeated L times (L is the positive integer), so that the first barrier film 5 with a predetermined thickness is formed.

The first barrier film 5 may be formed with a thickness of 0.5 nm to 8 nm. In other cases, the first barrier film 5 may be formed with a thickness of 1 nm to 8 nm. In other cases, the first barrier film 5 may be formed with a thickness of 2 nm to 8 nm The first barrier film 5 with the thickness mentioned above suppresses the diffusion of nitrogen into the first capacitive insulating film 4 in the step of forming the second electrode 6, which will be described later. On the other hand, if the thickness of the first barrier film 5 is smaller than 0.5 nm, it is not easy to prevent the diffusion of the nitrogen to the first capacitive insulating film 4 in the step of forming the second electrode 6. If the thickness of the first barrier film 5 exceeds 8 nm, processability as the capacitor element is poor and an electrical resistance value is too high as the barrier film.

The thickness of the first barrier film 5 may be 5 nm or less when the capacitor element is applied to the generation of 50 nm or less of the DRAMs. In this case, the thickness of the first barrier film 5 may be 4 nm or less. The capacitor element has a three-dimensional structure with a short distance between electrodes. The first barrier film 5 with a thickness in these ranges is high in gap-filling property.

The first barrier film 5 in the present embodiment is formed by depositing the zinc oxide atomic layer and the atomic layer of the oxide of the impurity using an ALD method. Thus, the first barrier film 5 is not a stack of a film of zinc oxide and another film of the oxide of the impurity which are bounded from each other through interface. The first barrier film 5 is an alternate repeat of different atomic layers, for example, the zinc oxide atomic layer and the atomic layer of the oxide of the impurity. The repeat of different atomic layers forms the above mentioned stack of different atomic layers.

Therefore, the first barrier film 5 is, as a whole, as an n-type zinc oxide film.

At this time, the cycle numbers (the number of times of N, M and L of FIG. 5) of step S1, step S2 and step S3 may be set in order to set a predetermined value for the impurity concentration of the first barrier film 5. When the first barrier film 5 is doped with boron, steps of forming a B₂O₃ film may be performed in step S2. When the first barrier film 5 is doped with gallium, steps of forming a Ga₂O₃ film may be performed in step S2. In step S2, an impurity is decided to form atomic layer of the oxide of the impurity on the atomic layer of zinc oxide, wherein the impurity is the element for the barrier film 5 together with zinc and oxygen. For example, it is possible to select, as the impurity, one of boron (B), gallium (Ga) and aluminum (Al) in the step S2.

The first barrier film 5 may have a concentration of the impurity element in the range of 1×10²⁰ atoms/cm³ to 1×10²² atoms/cm³. For example, the first barrier film 5 may have a concentration of the impurity element at approximately 1×10²¹ atoms/cm³. The first barrier film 5 with the concentration of the impurity element in this range may have sufficiently high conductivity.

### Step of Forming the Second Electrode 6

Then, the second electrode 6 including the second metal nitride is formed on the first barrier film 5 as illustrated in FIG. 4. It is preferable to use titanium nitride as the second metal nitride.

At this time, in order to form the second electrode 6 using titanium nitride, it may use, for example, a CVD method or an ALD method which uses TiCl₄ and NH₃ as source gases, in the same manner as that of the first electrode 3. The second electrode includes titanium nitride alone or in combination with other materials. In some cases, a stacked film may be used, which has been obtained by depositing a conductive film including other source materials on a titanium nitride film. In other cases, a single layer of titanium nitride may be used.

In this way, the capacitor element having the MIM structure is formed.

The capacitor element of the present embodiment has a configuration in which the first electrode 3, the first capacitive insulating film 4, the first barrier film 5, and the second electrode 6 are sequentially stacked from the side of the semiconductor substrate 1. The first electrode 3 includes the first metal nitride. The first capacitive insulating film 4 includes zirconium oxide. The first barrier film 5 doped with at least one of boron, aluminum and gallium as an impurity includes the atomic layer of zinc oxide and the atomic layer of the oxide of the impurity. The second electrode 6 includes the second metal nitride.

The first barrier film 5 is doped with at least one of boron (B), aluminum (Al) and gallium (Ga) as an impurity to form an n-type semiconductor. The first barrier film 5 is provided between the first capacitive insulating film 4 and the second electrode 6. By this structure, the first capacitive insulating film 4 can be prevented from being directly exposed to a nitrogen-containing atmosphere when forming the metal nitride used as the second electrode 6. Consequently, the diffusion of nitrogen into the first capacitive insulating film 4 can be suppressed. When heat treatment is performed in a step after the second electrode 6 is formed, it is also possible suppress the diffusion of the nitrogen from the second electrode 6 to the first capacitive insulating film 4. Since the first barrier film 5 has conductivity, the first barrier film 5 will prevent reduction in the capacitance of the capacitor element.

By providing the configuration described above between the first electrode 3 and the second electrode 6, it is possible to form the capacitor element having an EOT value which is smaller than 0.9 nm without increase in the leakage current.

### Second Embodiment

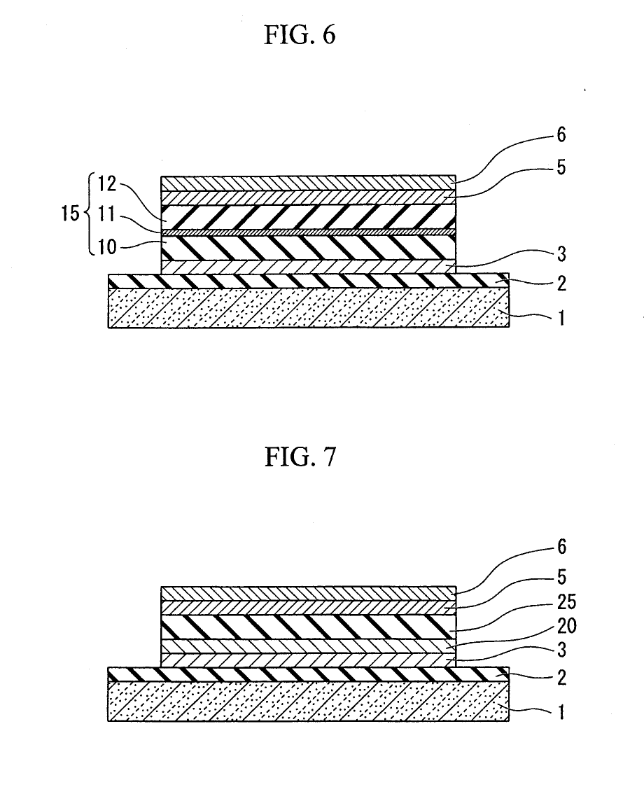

The configuration of a capacitor element according to a second embodiment of the present invention will be described with reference to FIG. 6. The same reference numerals are used to designate the same elements as those of the capacitor elements according to the first embodiment, and duplicate descriptions thereof will be omitted.

The capacitor element according to the present embodiment briefly includes a first electrode 3, a first capacitive insulating film 4, a first barrier film 5, and a second electrode 6, which are formed on a semiconductor substrate 1 and an interlayer insulating film 2. The capacitor element according to the present embodiment is substantially the same as that of the first embodiment, except that a second capacitive insulating film 15 having a stacked structure is formed instead of the first capacitive insulating film 4. Hereinafter, the configuration of the second capacitive insulating film 15 will be described.

The second capacitive insulating film 15 is formed to cover the first electrode 3. The second capacitive insulating film 15 has a configuration in which a first layer 10 of a capacitive insulating film, an aluminum oxide film 11, and a second layer 12 of a capacitive insulating film are sequentially stacked in this order over the semiconductor substrate 1. The first layer 10 of the capacitive insulating film and the second layer 12 of the capacitive insulating film include a zirconium oxide film or a hafnium oxide film.

Here, the aluminum oxide film 11 with a thickness of 0.5 nm or less may be formed. The aluminum oxide film 11 with the thickness of 0.5 nm or less can sufficiently reduce a leakage current while maintaining the capacitance of the capacitor element. On the other hand, if the thickness of the aluminum oxide film 11 exceeds 0.5 nm, the capacitance of the capacitor element is reduced.

The first barrier film 5 is formed to cover the second capacitive insulating film 15 (the second layer 12 of the capacitive insulating film). The second electrode 6 is further formed to cover the second capacitive insulating film 15.

According to the capacitor element of the present embodiment, the second capacitive insulating film 15 has a stack of the first layer 10 of the capacitive insulating film, the aluminum oxide film 11, and the second layer 12 of the capacitive insulating film. By the structure of the second capacitive insulating film 15, the total capacitance is reduced while it is possible to further reduce a leakage current. As described above, the aluminum oxide film 11 is provided between the first layer 10 of the capacitive insulating film and the second layer 12 of the capacitive insulating film. The grain boundary between the first layer 10 of the capacitive insulating film and the second layer 12 of the capacitive insulating film is divided by the aluminum oxide film 11, resulting in the suppression of a leakage current.

The structure of the second capacitive insulating film 15 is not limited to the stack of the first layer 10 of the capacitive insulating film, the aluminum oxide film 11, and the second layer 12 of the capacitive insulating film. For example, it may employ a nano-laminated structure in which an aluminum oxide film and other material film are alternately stacked in an atomic layer level using an ALD method. That is, if the aluminum oxide film 11 is formed in the second capacitive insulating film 15 to divide the second capacitive insulating film 15, the number of layers to be stacked is not limited.

The second electrode 6 including the second metal nitride is formed on the second capacitive insulating film 15. It is preferable for the second metal nitride to be titanium nitride. However, the present embodiment is not limited thereto. For example, other materials may be used, as long as the second metal nitride is a metal nitride. As other electrode materials, for example, tungsten nitride (WN), tantalum nitride (TaN) and the like may be used. Furthermore, the first electrode 3 and the second electrode 6 may be formed using different metal nitrides.

Next, a manufacturing method of the capacitor element according to the second embodiment will be described with reference to FIG. 6. The same reference numerals are used to designate the same elements as those of the capacitor element according to the first embodiment, and detailed description thereof will be omitted.

The manufacturing method of the capacitor element according to the present embodiment briefly includes a step of forming the first electrode 3, a step of forming the second capacitive insulating film 15 on the first electrode 3, a step of forming the first barrier film 5 on the second capacitive insulating film 15, and a step of forming the second electrode 6 on the first barrier film 5. The manufacturing method of the capacitor element according to the present embodiment is substantially the same as that of the first embodiment, except that the second capacitive insulating film 15 is formed instead of the first capacitive insulating film 4. Hereinafter, a method of forming the second capacitive insulating film 15 will be described.

First, the semiconductor substrate 1 on which the first electrode 3 for a capacitor element is formed is prepared. The first layer 10 of the capacitive insulating film is formed using an ALD method to cover the first electrode 3. The aluminum oxide film 11 is formed to cover the first layer 10 of the capacitive insulating film. The second layer 12 of the capacitive insulating film is formed to cover the aluminum oxide film 11. Accordingly, the second capacitive insulating film 15 is formed.

The second capacitive insulating film 15 is not limited to such a stacked structure. For example, it may be possible to employ a nano-laminated structure in which a zirconium oxide film and other materials are alternately stacked in an atomic layer level using an ALD method.

At this time, the aluminum oxide film 11 with a thickness of 0.5 nm or less may be formed. The aluminum oxide film 11 with the thickness of 0.5 nm or less can reduce a leakage current while maintaining the capacitance of the capacitor element.

Thereafter, the first barrier film 5 and the second electrode 6 are sequentially formed on the second capacitive insulating film 15, so that the capacitor element of the present embodiment is formed.

The present embodiment has a configuration in which the aluminum oxide film 11 is formed in the second capacitive insulating film 15 to divide the second capacitive insulating film 15. By providing the aluminum oxide film 11, it is possible to divide the grain boundary of the second capacitive insulating film 15. Consequently, the total capacitance is reduced while it is possible to further reduce a leakage current.

### Third Embodiment

Next, the configuration of a capacitor element according to a third embodiment of the present invention will be described with reference to FIG. 7.

The capacitor element according to the present embodiment briefly includes a first electrode 3, a second barrier film 20, a third capacitive insulating film 25, a first barrier film 5, and a second electrode 6, which are formed on a semiconductor substrate 1 and an interlayer insulating film 2. The capacitor element according to the present embodiment is substantially the same as that of the first embodiment, except that the second barrier film 20 including a zinc oxide film doped with at least one of boron, aluminum and gallium as an impurity is formed between the first electrode 3 and the third capacitive insulating film 25.

A manufacturing method of the capacitor element according to the third embodiment of the present invention briefly includes a step of forming the first electrode 3, a step of forming the second barrier film 20 on the first electrode 3, a step of forming the third capacitive insulating film 25 on the second barrier film 20, a step of forming the first barrier film 5 on the third capacitive insulating film 25, and a step of forming the second electrode 6 on the first barrier film 5.

According to the present embodiment, the second barrier film 20 including the zinc oxide film doped with at least one of boron, aluminum and gallium as the impurity is formed between the first electrode 3 and the third capacitive insulating film 25. Accordingly, it is possible to prevent the diffusion of nitrogen from the first electrode 3 to the third capacitive insulating film 25. The second barrier film 20 having the structure described above may be effective to suppress the diffusion of nitrogen from the first electrode 3 into the third capacitive insulating film 25, even when a heat treatment is performed after the first electrode 3 is formed. The heat treatment would cause the diffusion of nitrogen in the absence of the second barrier film 20. The present embodiment can be applied to the case of using the first electrode 3 having at least an upper surface formed of a metal nitride as described above. When it is possible to ignore the diffusion of the nitrogen to a capacitive insulating film from the capacitor electrodes after forming the capacitor electrodes, the barrier film may be arranged only between the capacitive insulating film and the second electrode 6. The barrier film between the capacitive insulating film and the second electrode 6 prevents the diffusion of the nitrogen when forming the second electrode 6 as described in the first embodiment.

### Fourth Embodiment

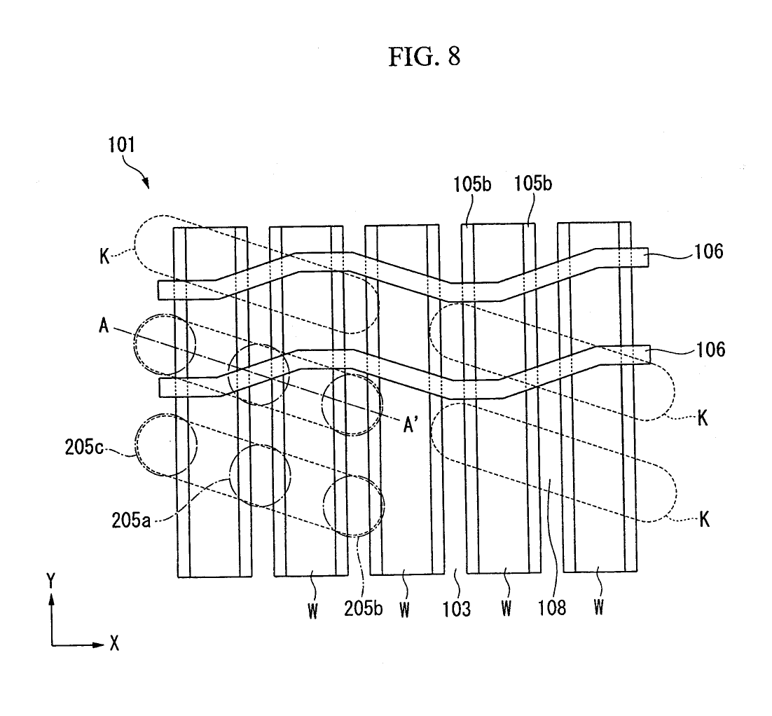

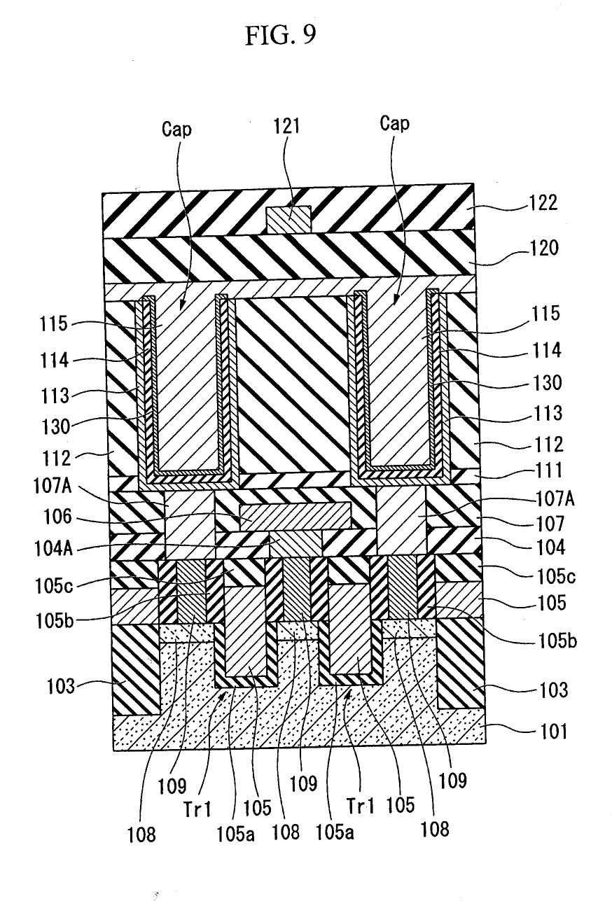

Next, the semiconductor device of the present embodiment will be described with reference to FIGS. 8 and 9. In the semiconductor device of the present embodiment, the stacked structures shown in the first to third embodiments of the present invention can be applied to a capacitor element.

FIG. 8 is a schematic diagram illustrating a planar layout of a memory cell part of a DRAM device to which the capacitor element is applied. FIG. 9 is a fragmentary sectional view illustrating a sectional structure of the semiconductor device corresponding to line A-A′ of FIG. 8. A capacitor element will be omitted in FIG. 8 but only in FIG. 9.

The memory cell part will be initially described with reference to FIG. 8. As illustrated in FIG. 8, the memory cell part briefly includes bit lines 106 extending in the X direction, word lines W extending in the Y direction, active regions K having an elongated strip shape, and impurity diffusion layers 108. Hereinafter, each element will be described.

A plurality of bit lines 106 extend in a zigzag shape (curved shape) in the X direction while being arranged at a predetermined interval in the Y direction.

Furthermore, a plurality of word lines W linearly extend in the Y direction while being arranged at a predetermined interval in the X direction. Furthermore, parts at which the word lines W cross the active regions K include the gate electrodes 105, which will be described later. Furthermore, the sidewalls 105b are formed at both sides of the word lines W along the Y direction.

The active regions K are formed on a surface of a semiconductor substrate 101. The active regions K are obliquely aligned rightward and downward in an elongated strip shape at a predetermined interval in the plain view. This is an arrangement according to the layout generally called the 6F2 memory cell.

Furthermore, the impurity diffusion layers 108 are formed at the center part and both end sides of the active region K. The impurity diffusion layers 108 function as source and drain regions of a MOS transistor Tr1, which will be described later. Substrate contact parts 205a to 205c having a circular shape are arranged just above the source and drain regions (the impurity diffusion layers).

On the semiconductor substrate 101, a plurality of isolation regions 103 linearly extend in the Y direction. The plurality of isolation regions 103 are formed at a predetermined interval in the X direction.

The substrate contact parts 205a to 205c are arranged such that each of the centers thereof is positioned between the word lines W. The central substrate contact part 205a overlaps the bit line 106.

The substrate contact parts 205a to 205c are at positions at which substrate contact plugs 109, which will be described later, are arranged. The substrate contact parts 205a to 205c are at parts in contact with the semiconductor substrate 101.

The memory cell part will be described with reference to FIG. 9. The memory cell part of a DRAM device according to the semiconductor device of the present embodiment briefly includes the MOS transistor Tr1, capacitor contact plugs 107A, the substrate contact plugs 109, and capacitor elements Cap. connected through the substrate contact plugs 109 and the capacitor contact plugs 107A and employing a stacked film including a metal oxide film with a thickness of 3 nm or less as the capacitive insulating film 114. The capacitor contact plugs 107A and the substrate contact plugs 109 are connected to the MOS transistor Tr1. The capacitor elements Cap is connected through the substrate contact plugs 109 and the capacitor contact plugs 107A. The capacitor elements Cap employ a stacked structure including a metal oxide film with a thickness of 3 nm or less as the capacitive insulating film 114. Hereinafter, each element will be described.

### MOS Transistor Tr1

The MOS transistor Tr1 briefly includes the semiconductor substrate 101, the isolation regions 103, the active regions K partitioned by the isolation regions 103, and two gate electrodes 105 recessed in the active regions K. The isolation regions 103 are provided for partitioning one surface of the semiconductor substrate 101.

The semiconductor substrate 101 is a semiconductor containing a predetermined concentration of P type impurity, for example, silicon (Si) containing a predetermined concentration of P type impurity. The isolation regions 103 are formed in the semiconductor substrate 101. The isolation regions 103 are formed by burying an insulating film such as a silicon oxide film (SiO₂) in surface regions of the semiconductor substrate 101 using a shallow trench isolation (STI) method. In this way, adjacent active regions K are isolated from each other. In the present embodiment, the present invention is applied to a cell structure in which a 2-bit memory cell is arranged in one active region K.

In the active region K, the impurity diffusion layers 108 functioning as source and drain regions are separated from each other. The impurity diffusion layer 108 is formed by introducing, for example, phosphorus into the semiconductor substrate 101 as an N type impurity. Furthermore, each of the recessed gate electrodes 105 is formed between the impurity diffusion layers 108.

The gate electrode 105 of the present embodiment is a groove-type gate electrode. The gate electrode 105 is buried in a groove formed over the semiconductor substrate 101 while protruding from the groove through the impurity diffusion layer 108.

Furthermore, the gate electrode 105 is formed of a multilayer of a polycrystalline silicon film containing an impurity and a metal film. The polycrystalline silicon film can be formed by adding an N type impurity such as phosphorus (P) at the time of film growth using a CVD method. As the metal film, a high melting point metal such as tungsten (W), tungsten nitride (WN) or tungsten silicide (WSi) can be used.

With such a configuration, the two gate electrodes 105 function as gate electrodes of the two MOS transistors Tr1, respectively, and the impurity diffusion layers 108 function as source and drain electrodes, respectively.

A gate insulating film 105a is formed between the gate electrode 105 and the semiconductor substrate 101. The sidewalls 105b include an insulating film such as silicon nitride (Si₃N₄). The sidewalls 105b are formed at sidewalls of parts of the gate electrode 105 which protrude from the semiconductor substrate 101. An insulating film 105c including silicon nitride is formed on the gate electrode 105 to protect an upper surface of the gate electrode 105.

The substrate contact plugs 109 are in contact with the impurity diffusion layers 108, respectively. The substrate contact plugs 109 are arranged at the positions of the substrate contact parts 205a to 205c illustrated in FIG. 8, respectively. The substrate contact plugs, for example, are formed from polycrystalline silicon containing phosphorus (P). The width in the lateral (X) direction of the substrate contact plug 109 is defined by the sidewalls 105b formed on adjacent gate wirings W. The substrate contact plug 109 has a self-aligned structure.

An interlayer insulating film 104 covers the insulating film 105c on the gate electrode 105. A bit line contact plug 104A is arranged at the position of the substrate contact plug 205a illustrated in FIG. 8 to pass through the interlayer insulating film 104. Thus, the bit line contact plug 104A is electrically connected to the substrate contact plug 109. The bit line contact plug 104A, for example, is formed by stacking tungsten (W) and the like on a barrier film (TiN/Ti) including a stack of titanium (Ti) and titanium nitride (TiN).

Furthermore, the bit line 106 is connected to the bit line contact plug 104A. The bit line 106 is formed of a stacked film including tungsten nitride (WN) and tungsten (W).

A second interlayer insulating film 107 covers the bit line 106 and the interlayer insulating film 104. The capacitor contact plugs 107A are connected to the substrate contact plugs 109 by passing through the second interlayer insulating film 107 and the interlayer insulating film 104. The capacitor contact plugs 107A are arranged at the positions of the substrate contact plugs 205b and 205c illustrated in FIG. 8.

A third interlayer insulating film 111 including silicon nitride covers the second interlayer insulating film 107. A fourth interlayer insulating film 112 including a silicon oxide film covers the third interlayer insulating film 111.

The capacitor element Cap is arranged inside the third interlayer insulating film 111 and the fourth interlayer insulating film 112. A first electrode 113 is connected to the capacitor contact plugs 107A by passing through the third interlayer insulating film 111 and the fourth interlayer insulating film 112. The first electrode 113 may be connected to the capacitor contact plugs 107A through a pad formed of a conductive film. The first electrode 113 is connected to the MOS transistor Tr1 through the capacitor contact plugs 107A.

The capacitor element Cap includes the first electrode 113, the capacitive insulating film 114, a barrier film 130, and a second electrode 115. The capacitive insulating film 114 covers the lateral sides of the first electrode 113. The capacitive insulating film 114 includes a zirconium oxide film or hafnium oxide. The barrier film 130 covers the capacitive insulating film 114. The barrier film 130 includes zinc oxide (ZnO) which is an n type semiconductor doped with at least one of boron (B), aluminum (Al) and gallium (Ga) as an impurity. That is to say, the capacitor element Cap has a structure in which the capacitive insulating film 114 is interposed between the first electrode 113 and the second electrode 115. The barrier film 130 is interposed between the second electrode 115 and the capacitive insulating film 114. The barrier film 130 is in contact with the capacitive insulating film 114. The barrier film 130 is in contact with the second electrode 115. The capacitor element Cap may be formed using the method of the second or third embodiment described above.

The barrier film 130 is an n type semiconductor doped with at least one of boron (B), aluminum (Al) and gallium (Ga) as an impurity. The barrier film 130 may be formed with a thickness of 0.5 nm to 8 nm. In other cases, the barrier film 130 may be formed with a thickness of 1 nm to 8 nm. In other cases, the barrier film 130 may be formed with a thickness of 2 nm to 8 nm. The first barrier film 5 may have a concentration of the impurity element in the range of 1×10²⁰ atoms/cm³ to 1×10²² atoms/cm³. In other cases, the first barrier film 5 may have a concentration of the impurity element at approximately 1×10²¹ atoms/cm³. The barrier film which includes the impurity at the concentration in the range described above has sufficient conductivity.

A fifth interlayer insulating film 120 is disposed on the second electrode 115. A wiring 121 is disposed on the fifth interlayer insulating film 120. A surface protective film 122 covers the fifth interlayer insulating film 120 and the wiring 121. The fifth interlayer insulating film 120 includes silicon oxide and the like. The wiring 121 includes aluminum (Al), copper (Cu) and the like.

A predetermined potential is applied to the second electrode 115 of the capacitor element Cap. Therefore, the presence or absence of charges held in the capacitor element Cap is determined, so that it can serve as a DRAM device which performs an information storage operation.

According to the semiconductor device of the present embodiment, the capacitive insulating film 114 and the barrier film 130 formed using the method of the present embodiment are formed between the first electrode 113 and the second electrode 115 of the capacitor element Cap. Thereby, the diffusion of nitrogen to the capacitive insulating film 114 is suppressed. Consequently, it is possible to achieve the capacitor element Cap having reduced leakage current and large capacitance. Furthermore, since the barrier film 130 is a conductor, it is possible to prevent the capacitance of the capacitor element Cap from being reduced by the barrier film 130.

Consequently, it is possible to form a capacitor element having an EOT value which is smaller than 0.9 nm without an increase in a leakage current. Thus, it is possible to provide the capacitor element Cap with high reliability. A DRAM device having the capacitor element Cap is formed so that it is possible to provide a high performance device with excellent data holding characteristics even in the case of high integration (miniaturization).

In the present embodiment, the capacitor element Cap is a cylinder type. The configuration of the capacitor element Cap will be described in detail with reference to FIG. 12.

The capacitor element Cap of the present embodiment includes the first electrode 113, the capacitive insulating film 114, the barrier film 130, and the second electrode 115. The capacitive insulating film 114 covers the lateral sides of the first electrode 113. The capacitive insulating film 114 includes a zirconium oxide film or hafnium oxide. The barrier film 130 covers the capacitive insulating film 114. The barrier film 130 includes zinc oxide doped with at least one of boron, aluminum and gallium as an impurity. The capacitor element Cap has a structure in which the capacitive insulating film 114 is interposed between the first electrode 113 and the second electrode 115. The barrier film 130 is interposed between the second electrode 115 and the capacitive insulating film 114.

The first electrode 113 includes a first metal nitride film. The first electrode 113 covers the inner side surfaces and bottom surfaces of opening holes 112A. The opening holes 112A are provided to penetrate the third interlayer insulating film 111 and the fourth interlayer insulating film 112.

The capacitive insulating film 114 including the zirconium oxide film or the hafnium oxide covers an inner side surface and a bottom surface of the first electrode 113.

The barrier film 130 covers an inner side surface and a bottom surface of the capacitive insulating film 114. The barrier film 130 includes a zinc oxide film doped with at least one of boron, aluminum and gallium as the impurity. The barrier film 130 functions as an n type semiconductor. Furthermore, the barrier film 130 may be formed with a thickness of 0.5 nm to 8 nm. In other cases, the barrier film 130 may be formed with a thickness of 1 nm to 8 nm. In other cases, the barrier film 130 may be formed with a thickness of 2 nm to 8 nm. The first barrier film 130 may have a concentration of the impurity element in the range of 1×10²⁰ atoms/cm³ to 1×10²² atoms/cm³. In other cases, the barrier film 130 may have a concentration of the impurity element at approximately 1×10²¹ atoms/cm³. The barrier film 130 with the concentration of the impurity element in this range may have sufficiently high conductivity.

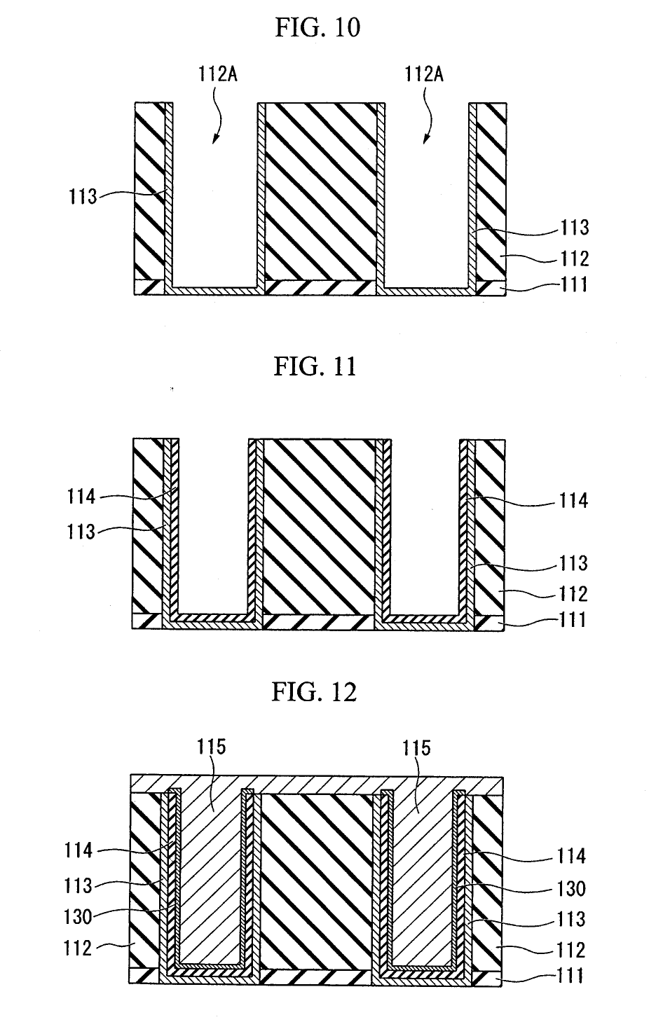

Next, a manufacturing method of the capacitor element Cap of the semiconductor device will be described with reference to FIGS. 10 to 12. FIGS. 10 to 12 are fragmentary cross sectional elevation views illustrating only elements formed on the third interlayer insulating film 111. Hereinafter, each step will be sequentially described.

As illustrated in FIG. 10, the fourth interlayer insulating film 112 is formed to cover the third interlayer insulating film 111. The opening holes 112A passing through the third interlayer insulating film 111 and the fourth interlayer insulating film 112 are formed using photolithography technology and dry etching technology. The surfaces of the capacitor contact plugs 107A are shown through the opening holes 112A. The opening holes 112A are positions at which the capacitor elements Cap are to be formed.

A first metal nitride film for the first electrode 113 is formed on the fourth interlayer insulating film 112 and inside the opening holes 112A. The first electrode 113 is formed to cover the inner side surface and bottom surface of the opening hole 112A using dry etching technology or chemical mechanical polishing (CMP) technology. At this time, the first metal nitride film, for example, is formed by sequentially depositing a titanium film and a titanium nitride film.

Then, the capacitive insulating film 114 including the zirconium oxide film or the hafnium oxide is deposited with a thickness of, for example, 6 nm to 7 nm to cover the side surface and the bottom surface of the first electrode 113 as illustrated in FIG. 11. Here, the capacitive insulating film 114 on a top surface of the fourth interlayer insulating film 112 is omitted.

Then, the barrier film 130 including the zinc oxide doped with at least one of boron, aluminum and gallium as an impurity is formed using an ALD method. The barrier film 130 is formed to cover the inner side surface and the bottom surface of the capacitive insulating film 114 as illustrated in FIG. 12. The barrier film 130 may be formed with a thickness of 0.5 nm to 8 nm. In other cases, the barrier film 130 may be formed with a thickness of 1 nm to 8 nm. In other cases, the barrier film 130 may be formed with a thickness of 2 nm to 8 nm. Furthermore, the type of impurity elements of a source gas is changed when a film is grown using the ALD method, so that the barrier film 130 can be doped with arbitrary impurities. The barrier film 130 may have a concentration of the impurity element in the range of 1×10²⁰ atoms/cm³ to 1×10²² atoms/cm³. In other cases, the barrier film 130 may have a concentration of the impurity element at approximately 1×10²¹ atoms/cm³.

Here, for example, the barrier film 130 including an n type zinc oxide film containing aluminum may be formed with a thickness of 2 nm to 3 nm.

The second electrode 115 including the second metal nitride is formed to fill the inside of the opening holes 112A and cover the upper surface of the fourth interlayer insulating film 112. At this time, the second electrode 115 and the first electrode 113 may be formed using different metal nitrides. The first electrode 113 and the second electrode 115 may be formed of a stack including a metal nitride film. The metal nitride films of the first electrode 113 and the second electrode 115 face the capacitive insulating film 114.

As described above, the capacitor element Cap of the present embodiment is completed.

Here, the capacitor element is a cylinder type using only the inner wall of the first electrode as an electrode, but is not limited thereto. It is possible to form a crown type capacitor element using both the outer wall and inner wall of the first electrode as an electrode or a pedestal type capacitor element using only the outer wall of the first electrode as an electrode.

According to the capacitor element Cap of the present embodiment, the capacitive insulating film 114 and the barrier film 130 formed using the method of the present embodiment can be formed between the first electrode 113 and the second electrode 115 of the capacitor element Cap. It is possible to suppress the diffusion of nitrogen to the capacitive insulating film 114. Consequently, it is possible to achieve the capacitor element Cap having a reduced leakage current and large capacitance. Since the barrier film 130 is conductive, it is possible to prevent the capacitance of the capacitor element Cap from being reduced by the barrier film 130.

Consequently, it is possible to form a capacitor element having an EOT value which is smaller than 0.9 nm without an increase in a leakage current. Thus, it is possible to provide the capacitor element Cap with high reliability. Furthermore, a DRAM device having the capacitor element Cap accomplishes to provide a high performance device with better data retention characteristics than other devices even in the case of high integration (miniaturization).

### EXAMPLE

Hereinafter, the present invention will be described in detail based on an Example. However, the present invention is not limited thereto.

### Example 1

As Example 1, a process of forming the bather film 130 using an ALD method will be described below.

A semiconductor substrate formed with the opening holes 112A was prepared. The first electrode 113 including a titanium nitride film with a thickness of 30 nm was formed. Next, the capacitive insulating film 114 with a thickness of about 6 nm was formed. The capacitive insulating film 114 was formed by the ALD method, at the substrate temperature of 230° C., using TEMAS gas as a Zr precursor and mixed gas of ozone and oxygen (O₃/O₂ gas) as an oxidizing agent. Then, the semiconductor substrate was installed in the reaction chamber of an ALD film forming apparatus.

### Step S1

Diethylzinc (DEZn) was introduced into the reaction chamber as a Zn source gas. A zinc film was deposited on a surface of the first capacitive insulating film 114. N₂ gas for purging was introduced into the reaction chamber and then the Zn source gas was discharged. Then, after oxygen (O₂) was introduced into the reaction chamber as an oxidizing agent, purging is performed using the N₂ gas. A zinc oxide atomic film at an atomic layer level was formed. Thereafter, Step Si was repeated.

### Step S2

Trimethylaluminum (TMA) was introduced into the reaction chamber as an Al source gas. Next, the N₂ gas for purging was introduced into the reaction chamber and the Al source gas was discharged. Then, after oxygen (O₂) was introduced into the reaction chamber as an oxidizing agent, purging was performed using the N₂ gas. An aluminum oxide film at an atomic layer level was formed. Thereafter, Step S2 was repeated.

Then, a cycle (Step S3) including Step Si and Step S2 was repeated, so that the first bather film 5 with a thickness of 3 nm was formed. Furthermore, when measuring the impurity element concentration of the first barrier film 5, the concentration of contained aluminum was about 1×10²¹ atoms/cm³. Thereafter, the second electrode 6 including a metal nitride was formed on the first barrier film 5. Thereby, the capacitor element Cap of the present example was completed.

When measuring the electrical characteristics of the capacitor element Cap obtained in the present example, EOT was 0.65 nm, and leakage current density was about 1×10⁻⁸ A/cm² under the conditions of a measurement temperature of 25° C. and bias of +1 V applied. The values of the EOT and the leakage current density are sufficient when the capacitor element Cap, for example, is used in a DRAM memory cell of a generation of a design rule of 35 nm or less.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a first capacitive insulating film;
a first electrode having a first surface containing nitrogen; and
a first barrier film between the first capacitive insulating film and the first electrode, the first barrier film facing the first surface of the first electrode, the first barrier film comprising zinc oxide, the first barrier film being conductive.

2. The semiconductor device according to claim 1, wherein a thickness of the first barrier film is 0.5 nm to 8 nm.

3. The semiconductor device according to claim 1, wherein the first barrier film contains an impurity,
wherein the first barrier film has a concentration of the impurity in the range of 1×10²⁰ atoms/cm³ to 1×10²² atoms/cm³.

4. The semiconductor device according to claim 1, wherein the first barrier film contains at least one of boron, aluminum, and gallium.

5. The semiconductor device according to claim 1, wherein the first barrier film comprises at least a first atomic layer of zinc oxide and a second atomic layer of one of boron oxide, aluminum oxide, and gallium oxide.

6. The semiconductor device according to claim 1, wherein the first barrier film comprises alternate lamination of first atomic layers of zinc oxide and second atomic layers of one of boron oxide, aluminum oxide, and gallium oxide.

7. The semiconductor device according to claim 1, wherein the first surface of the first electrode comprises metal nitride.

8. The semiconductor device according to claim 1, wherein the first capacitive insulating film comprises one of zirconium oxide and hafnium oxide.

9. The semiconductor device according to claim 1, wherein the first capacitive insulating film comprises:
first and second capacitive layers; and
an aluminum oxide layer between the first and second capacitive layers.

10. The semiconductor device according to claim 1, further comprising:
a second electrode in contact with the first capacitive insulating film, the first capacitive insulating film and the first barrier film being between the first and second electrodes.

11. The semiconductor device according to claim 1, further comprising:
a second barrier film in contact with the first capacitive insulating film, the second barrier film comprising zinc oxide, the second barrier film containing at least one of boron, aluminum, and gallium;
a second electrode in contact with the second barrier film.

12. A semiconductor device comprising:
a first electrode containing a first metal nitride;
a second electrode containing a second metal nitride;
a capacitive insulating film between the first and second electrodes, the capacitive insulating film comprising one of zirconium oxide and hafnium oxide; and
a first barrier film between the second electrode and the capacitive insulating film, the first barrier film being in contact with the second electrode and the capacitive insulating film, the first barrier film comprising zinc oxide, the first barrier film containing at least one of boron, aluminum, and gallium.

13. The semiconductor device according to claim 12, wherein the first barrier film comprises at least a first atomic layer of zinc oxide and a second atomic layer of one of boron oxide, aluminum oxide, and gallium oxide.

14. The semiconductor device according to claim 12, wherein the first barrier film comprises alternate lamination of first atomic layers of zinc oxide and second atomic layers of one of boron oxide, aluminum oxide, and gallium oxide.

15. The semiconductor device according to claim 12, wherein a thickness of the first barrier film is 0.5 nm to 8 nm.

16. The semiconductor device according to claim 12, further comprising:
a second barrier film between the first electrode and the first capacitive insulating film, the second barrier film comprising zinc oxide, the second barrier film containing at least one of boron, aluminum, and gallium.

17. A semiconductor device comprising:
a transistor; and
a capacitor element electrically coupled to the transistor,
wherein the capacitor element comprises:
a first electrode containing a first metal nitride, the first electrode electrically coupled to the transistor;
a second electrode containing a second metal nitride;
a capacitive insulating film between the first and second electrodes, the capacitive insulating film comprising one of zirconium oxide and hafnium oxide; and
a first barrier film between the second electrode and the capacitive insulating film, the first barrier film being in contact with the second electrode and the capacitive insulating film, the first barrier film comprising zinc oxide, the first barrier film containing at least one of boron, aluminum, and gallium.

18. The semiconductor device according to claim 17, wherein the first barrier film comprises at least a first atomic layer of zinc oxide and a second atomic layer of one of boron oxide, aluminum oxide, and gallium oxide.

19. The semiconductor device according to claim 17, wherein the first barrier film comprises alternate lamination of first atomic layers of zinc oxide and second atomic layers of one of boron oxide, aluminum oxide, and gallium oxide.

20. The semiconductor device according to claim 17, wherein a thickness of the first bather film is 0.5 nm to 8 nm.
